(19) United States
(12) Patent Application Publication
(10) Pub. No.: US 2026/0003288 A1
(43) Pub. Date: Jan. 1, 2026

(54) BOWL AND SUBSTRATE TREATMENT APPARATUS

(71) Applicant: SEMES CO., LTD., Cheonan-si (KR)

(72) Inventors: A Rah CHO, Daejeon (KR); Jong Wha KANG, Seongnam-si (KR); Eun Hyeok CHOI, Cheonan-si (KR); Byoung Doo CHOI, Cheonan-si (KR)

(21) Appl. No.: 19/048,857

(22) Filed: Feb. 8, 2025

(30) Foreign Application Priority Data
Jun. 28, 2024 (KR) 10-2024-0084926

(51) Int. Cl. G03F 7/30; G03F 7/16

(52) U.S. Cl. CPC G03F 7/3092; G03F 7/162

(57) ABSTRACT

The present disclosure provides a bowl and a substrate treatment apparatus.

The bowl includes: a bowl body disposed around a support unit supporting and rotating a substrate, and having an exhaust pipe formed in a lower portion thereof to be connected to an exhaust duct disposed in a lower side thereof; and an outlet guide formed in a lower portion of the exhaust pipe and having an outlet opening formed in an extension direction of the exhaust duct oriented toward an exhaust portion so as to guide gas introduced into the exhaust pipe from the bowl body, to the exhaust portion of the exhaust duct.

### CROSS-REFERENCE TO RELATED APPLICATION(S)

This application claims benefit of priority to Korean Patent Application No. 10-2024-0084926 filed on Jun. 28, 2024, in the Korean Intellectual Property Office, the disclosure of which is incorporated herein by reference in its entirety.

### BACKGROUND

### 1. Field

The present disclosure relates to a bowl used in a treatment process of a substrate, and a substrate treatment apparatus.

### 2. Description of Related Art

In order to manufacture a semiconductor device, various processes such as cleaning, deposition, photo, etching, and ion implantation are performed. Among these processes, the photo process may include a coating process in which a photosensitive liquid such as photoresist is applied to a surface of a substrate to form a film, an exposure process in which a circuit pattern is transferred to the film formed on the substrate, and a development process in which the film formed on the substrate is selectively removed from an exposed region or an opposite region thereof.

A substrate treatment apparatus used in a coating process in which a photosensitive liquid such as photoresist is applied to form a film may include a cup-shaped bowl having a treatment space, a support unit supporting and rotating a substrate in the treatment space, and a nozzle unit supplying photoresist to a substrate placed on the support unit.

An exhaust unit is coupled to a bottom of the bowl to exhaust an atmosphere of the treatment space. In general, the exhaust unit includes an integrated duct for connecting a plurality of exhaust pipes respectively connected to a plurality of bowls, and a plurality of treatment spaces may be exhausted simultaneously through the integrated duct.

### PRIOR ART REFERENCE

### Patent Document

(Patent Document 1) Korean Laid-open Patent Publication No. 10-2008-0009836

### SUMMARY

An aspect of the present disclosure is to provide a bowl increasing the exhaust efficiency of the bowl.

In order to achieve the above-described aspect, a bowl according to an embodiment of the present disclosure includes: a bowl body disposed around a support unit supporting and rotating a substrate, and having an exhaust pipe formed in a lower portion thereof to be connected to an exhaust duct disposed in a lower side thereof; and an outlet guide formed in a lower portion of the exhaust pipe and having an outlet opening formed in an extension direction of the exhaust duct oriented toward an exhaust portion so as to guide gas introduced into the exhaust pipe from the bowl body, to the exhaust portion of the exhaust duct.

A body of the outlet guide may be formed by curvedly extending from an upper end of the outlet guide toward the outlet opening.

An angle from the upper end of the outlet guide to the outlet opening may be 10° to 130°.

The exhaust pipe may be formed in a vertical direction.

The exhaust pipe may have a convexly curved shape in a rotational direction of the gas within the bowl body.

The exhaust pipe may have formed to be inclined in a rotational direction of the gas within the bowl body as the exhaust pipe moves downwardly.

The bowl of the present disclosure may further include an inlet guide formed in an upper portion of the exhaust pipe and having an inlet opening formed therein to at least partially face a rotational direction of the gas within the bowl body.

A body of the inlet guide may be formed to curvedly extend from a lower end of the inlet guide to the inlet opening.

An angle from the lower end of the inlet guide to the inlet opening may be 10° to 130°.

According to another aspect of the present disclosure, provided is a bowl including: a bowl body disposed around a support unit supporting and rotating a substrate and having an exhaust pipe formed in a lower portion thereof to be connected to an exhaust duct disposed in a lower side thereof; and an inlet guide formed in an upper portion of the exhaust pipe, and having an inlet opening formed therein to at least partially face a rotational direction of the gas within the bowl body so as to guide the gas within the bowl body to the exhaust pipe.

According to yet another aspect of the present disclosure, provided is a substrate treatment apparatus including: a process chamber; a support unit supporting and rotating a substrate within the process chamber; a nozzle unit discharging a chemical to the substrate; a bowl disposed within the process chamber; an exhaust duct disposed in a lower side of the bowl and having an exhaust portion formed therein; an exhaust pipe formed in a lower portion of the bowl to be inserted into the exhaust duct or formed in an upper portion of the exhaust duct to be inserted into the bowl, so as to connect the bowl and the exhaust duct; an outlet guide formed in the lower portion of the exhaust pipe and having an outlet opening formed in an extension direction of the exhaust duct oriented toward an exhaust portion of the exhaust duct; and an inlet guide formed in an upper portion of the exhaust pipe, and having an inlet opening formed to at least partially face a rotational direction of the gas.

The present disclosure may guide gas exhausted from a bowl to an exhaust duct through an exhaust pipe to increase the gas exhaust efficiency from the bowl to the exhaust duct, thereby decreasing a reduction amount of flow rate of gas passing through the exhaust pipe even when the rotation speed of the gas increases.

Accordingly, the present disclosure may prevent the occurrence of substrate defects by preventing the backflow of gas in the bowl.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view illustrating a substrate treatment facility according to an embodiment of the present disclosure;

FIG. 2 is a view of the substrate treatment facility of FIG. 1 viewed from an upper portion;

FIG. 3 is a view of the substrate treatment facility of FIG. 2 as viewed in a direction A-A;

FIG. 4 is a view of the substrate treatment facility of FIG. 2 as viewed in a direction B-B;

FIG. 5 is a schematic diagram illustrating the inside of the substrate treatment apparatus according to the present disclosure;

FIG. 6 is a cutaway perspective view illustrating an exhaust duct and a bowl according to the conventional art;

FIG. 7 is a cross-sectional view taken along line I-I of FIG. 6;

FIG. 8 is a cutaway perspective view illustrating an exhaust duct of the substrate treatment apparatus of FIG. 5 and a bowl according to a first embodiment;

FIG. 9 is a side view of the bowl of FIG. 8;

FIG. 10 is a cross-sectional view of a bowl according to a second embodiment of the present disclosure;

FIG. 11 is a cross-sectional view of a bowl according to a third embodiment of the present disclosure;

FIG. 12 is a cross-sectional view of a bowl according to a fourth embodiment of the present disclosure;

FIG. 13 is a cross-sectional view of a bowl according to a fifth embodiment of the present disclosure; and

FIG. 14 is a graph illustrating a comparison between the conventional art and the present disclosure according to the third embodiment of FIG. 11, with respect to the reduction in a passing flow rate of gas to the exhaust pipe.

### DETAILED DESCRIPTION

Hereinafter, preferred example embodiments will be described in detail with reference to the accompanying drawings so that those of ordinary skill in the art may easily implement the present disclosure. However, in describing preferred example embodiments of the present disclosure in detail, when it is determined that a detailed description of related known functions or configurations may unnecessarily obscure the gist of the present disclosure, the detailed description thereof will be omitted. Furthermore, the same reference numbers are used throughout the drawings to refer to the same or similar portions. Furthermore, in the present specification, it may be understood that the expressions such as “on,” “above,” “upper,” “below,” “beneath,” “lower,” and “side,” merely indicated based on drawings, and may actually vary depending on the direction in which the components are disposed.

Furthermore, throughout the specification, the terms “connected to” or “coupled to” are used to designate a connection or coupling of one element to another element and include both a case where an element is “directly connected or coupled to” another element and a case where an element is “indirectly connected or coupled to” another element via still another element. Furthermore, when a certain portion “includes” or “comprises” a certain component, this indicates that other components are not excluded and may be further included unless otherwise noted, and may be further included.

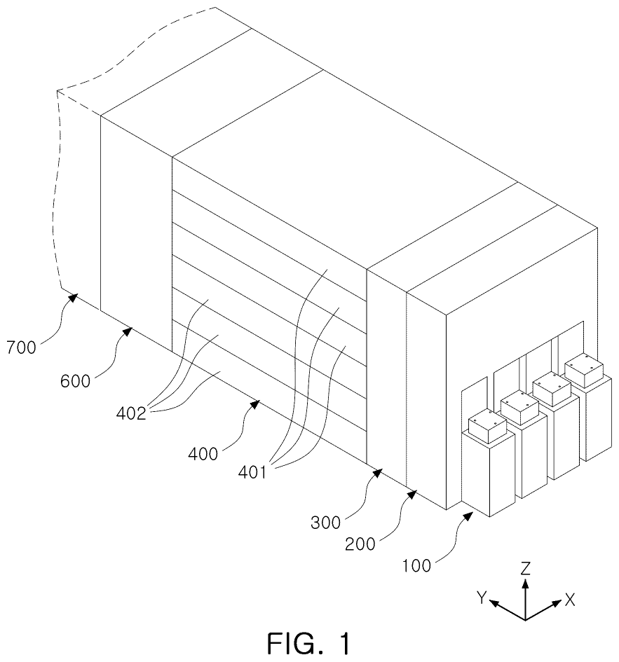

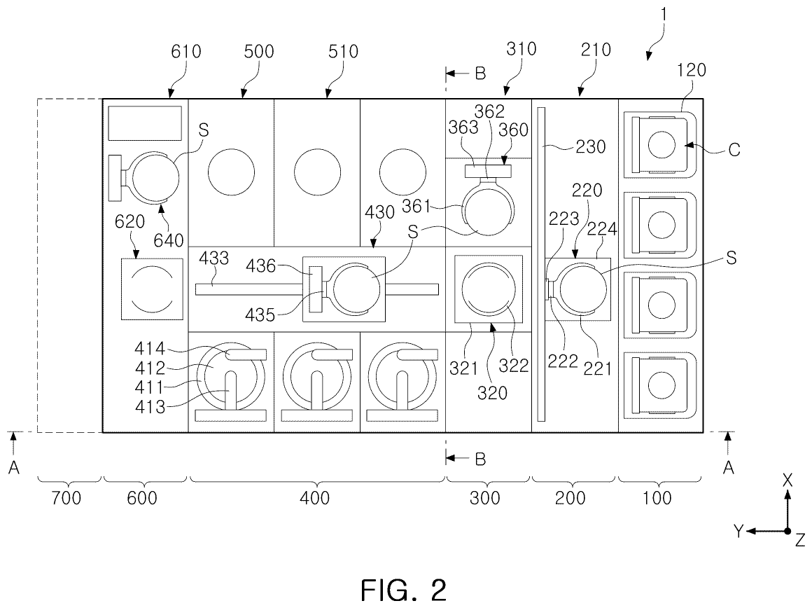

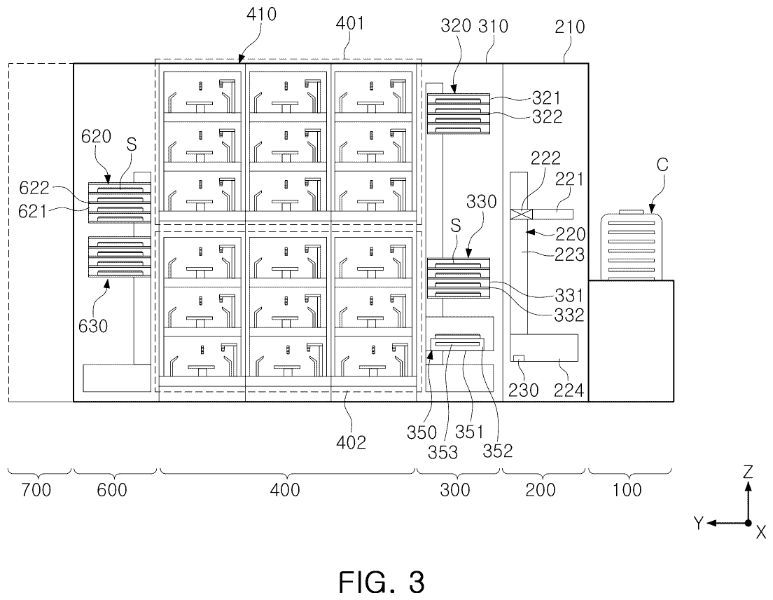

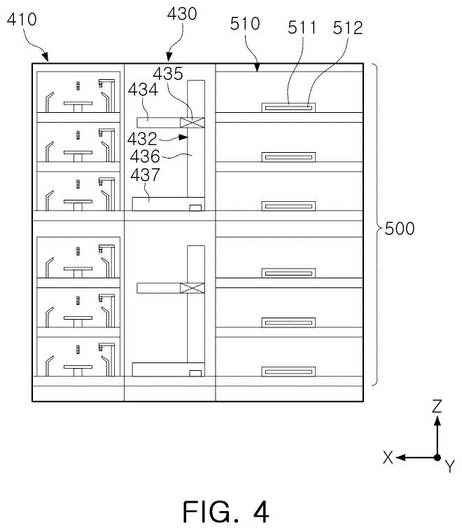

FIG. 1 is a perspective view illustrating a substrate treatment facility according to an embodiment of the present disclosure, FIG. 2 is a view of the substrate treatment facility of FIG. 1 viewed from an upper portion, FIG. 3 is a view of the substrate treatment facility of FIG. 2 as viewed in a direction A-A, and FIG. 4 is a view of the substrate treatment facility of FIG. 2 as viewed in a direction B-B.

Referring to FIGS. 1 to 4, a substrate treatment facility 1 includes a load port 100, an index module 200, a buffer module 300, a coating and development module 400, and an interface module 600. The load port 100, the index module 200, the buffer module 300, the coating and development module 400 and the interface module 600 are sequentially arranged in a single direction.

Hereinafter, a direction in which the load port 100, the index module 200, the buffer module 300, the coating and development module 400 and the interface module 600 are arranged is referred to as a first direction (Y-direction), a direction, perpendicular to the first direction (Y-direction) when viewed from an upper portion is referred to as a second direction (X-direction), and a direction, perpendicular to the first direction (Y-direction) and the second direction (X-direction) is referred to as a third direction (Z-direction).

A substrate S is moved in a state of being stored in a carrier C. The carrier C has a structure that may be sealed from the outside. For example, a front open unified pod (FOUP) having a door in the front may be used as the carrier C.

Hereinafter, the load port 100, the index module 200, the buffer module 300, the coating and development module 400 and the interface module 600 will be described in detail.

The load port 100 has a mounting table 120 on which the carrier C including the substrate S is placed. A plurality of mounting tables 120 are provided, and the mounting tables 120 are disposed in a row in the second direction (X-direction). In FIG. 2, an example in which four mounting tables 120 are provided is illustrated, but the number thereof may be changed.

The index module 200 transfers the substrate S between the carrier C placed on a mounting table 120 of the load port 100 and the buffer module 300. The index module 200 includes a frame 210, an index robot 220, and a guide rail 230. The frame 210 is generally provided in a shape of a rectangular solid with an empty interior, and is disposed between the load port 100 and the buffer module 300. The frame 210 of the index module 200 may be provided at a lower height than a frame 310 of the buffer module 300. The index robot 220 and the guide rail 230 are disposed within the frame 210. The index robot 220 is provided so that a hand 221 for directly handling the substrate S is capable of moving and rotating in the first direction (Y-direction), the second direction (X-direction), and the third direction (Z-direction). The index robot 220 includes the hand 221, an arm 222, a support 223, and a pedestal 224. The hand 221 is fixedly installed in the arm 222. The arm 222 is provided with an elastic structure and a rotatable structure. The support 223 is provided so that a longitudinal direction thereof is disposed in the third direction (Z-direction). The arm 222 is coupled to the support 223 so as to be movable along the support 223. The support 223 is fixedly coupled to the pedestal 224. The guide rail 230 is provided so that a longitudinal direction thereof is disposed in the second direction (X-direction). The pedestal 224 is coupled to the guide rail 230 so as to be able to move linearly along the guide rail 230. Additionally, although not illustrated, the frame 210 is further provided with a door opener for opening and closing a door of the carrier C.

The buffer module 300 includes the frame 310, a first buffer 320, a second buffer 330, a cooling chamber 350, and a first buffer robot 360. The frame 310 is provided in the shape of a rectangular solid with an empty interior, and is disposed between the index module 200 and the coating and development module 400. The first buffer 320, the second buffer 330, the cooling chamber 350 and the first buffer robot 360 are disposed within the frame 310. The cooling chamber 350, the second buffer 330 and the first buffer 320 are sequentially arranged from a lower portion in the third direction (Z-direction). The first buffer 320 is disposed at a height corresponding to a coating module 401 of the coating and development module 400, and the second buffer 330 and the cooling chamber 350 are provided at a height corresponding to a development module 402 of the coating and development module 400. The first buffer robot 360 is spaced part by a certain distance from the second buffer 330, the cooling chamber 350, and the first buffer 320 in the second direction (X-direction). The first buffer 320 and the second buffer 330 temporarily store a plurality of substrates S, respectively. The second buffer 330 has a housing 331 and a plurality of supports 332. The supports 332 are disposed in the housing 331, and are spaced apart from each other in the third direction (Z-direction). One substrate S is placed on each of the supports 332. The housing 331 has an opening in a direction in which the index robot 220 is provided and in a direction in which the first buffer robot 360 is provided, in order for the index robot 220 and the first buffer robot 360 to load or unload the substrate S into the support 332 in the housing 331. The first buffer 320 has a structure that is generally similar to that of the second buffer 330. However, a housing 321 of the first buffer 320 has an opening in a direction in which the first buffer robot 360 is provided and in a direction in which a coating robot 432 disposed in the coating module 401 is provided. The number of supports 322 provided in the first buffer 320 and the number of supports 332 provided in the second buffer 330 may be identical to or different from each other. In one example, the number of supports 332 provided in the second buffer 330 may be greater than the number of supports 322 provided in the first buffer 320.

The first buffer robot 360 transfers the substrate S between the first buffer 320 and the second buffer 330 as illustrated in FIG. 2. The first buffer robot 360 includes a hand 361, an arm 362, and a support 363. The hand 361 is fixedly installed in the arm 362. The arm 362 is provided with a flexible structure, and enables the hand 361 to move in the second direction (X-direction). The arm 362 is connected to the support 363 so as to be able to move linearly in the third direction (Z-direction) along the support 363. The support 363 has a length extending from a position corresponding to the second buffer 330 to a position corresponding to the first buffer 320. The support 363 may be provided to be longer in an upper or lower direction than the length thereof. The first buffer robot 360 may be provided so that the hand 361 is driven only in two axes in the second direction (X-direction) and the third direction (Z-direction).

The cooling chamber 350 cools the substrate S as illustrated in FIG. 3. The cooling chamber 350 includes a housing 351 and a cooling plate 352. The cooling plate 352 has an upper surface on which the substrate S is placed and a cooling means 353 cooling the substrate S. As the cooling means 353, various methods such as cooling by cooling water or cooling using a thermoelectric device may be used. Additionally, the cooling chamber 350 may be provided with a lift pin assembly positioning the substrate S on the cooling plate 352. The housing 351 has an opening in the direction in which the index robot 220 is provided and in a direction in which a development robot is provided, in order for the index robot 220 and the development robot provided in the development module 402 to load or unload the substrate S in the cooling plate 352. Additionally, the cooling chamber 350 may be provided with doors opening or closing the above-described opening.

The coating module 401 includes a process of coating the substrate S with a photosensitive liquid such as a photoresist and a heat treatment process such as heating and cooling the substrate S before and after t resist application process. The coating module 401 has a coating chamber 410, a baking chamber portion 500, and a transfer chamber 430. The coating chamber 410, the transfer chamber 430, and the baking chamber portion 500 are sequentially arranged in the second direction (X-direction). That is, based on the transfer chamber 430, the coating chamber 410 is provided on one side of the transfer chamber 430, and the baking chamber portion 500 is provided on the other side of the transfer chamber 430.

The coating chamber 410 is provided in plural, and a plurality of coating chamber 410 are provided in the first direction (Y-direction) and the third direction (Z-direction), respectively. The baking chamber portion 500 includes a plurality of baking chambers 510, and the plurality of baking chambers 510 are provided in the first direction (Y-direction) and the third direction (Z-direction), respectively. The transfer chamber 430 is disposed to be parallel to the first buffer 320 of the buffer module 300 in the first direction (Y-direction). The coating robot 432 and a guide rail 433 are disposed in the transfer chamber 430. The transfer chamber 430 has a generally rectangular shape. The coating robot 432 transfers the substrate S between the baking chamber 510, the coating chamber 410, and the first buffer 320 of the buffer module 300.

The guide rail 433 is disposed so that a longitudinal direction thereof is parallel to the first direction (Y-direction). The guide rail 433 guides the coating robot 432 to move linearly in the first direction (Y-direction). The coating robot 432 has a hand 434, an arm 435, a support 436, and a pedestal 437, as illustrated in FIG. 4. The hand 434 is fixedly installed in the arm 435. The arm 435 is provided with an elastic structure so that the hand 434 may move in a horizontal direction. The support 436 is provided so that a longitudinal direction thereof is disposed in the third direction (Z-direction). The arm 435 is coupled to the support 436 so that the arm 435 may move linearly in the third direction (Z-direction) along the support 436. The support 436 is fixedly coupled to the pedestal 437, and the pedestal 437 is coupled to the guide rail 433 so as to be movable along the guide rail 433.

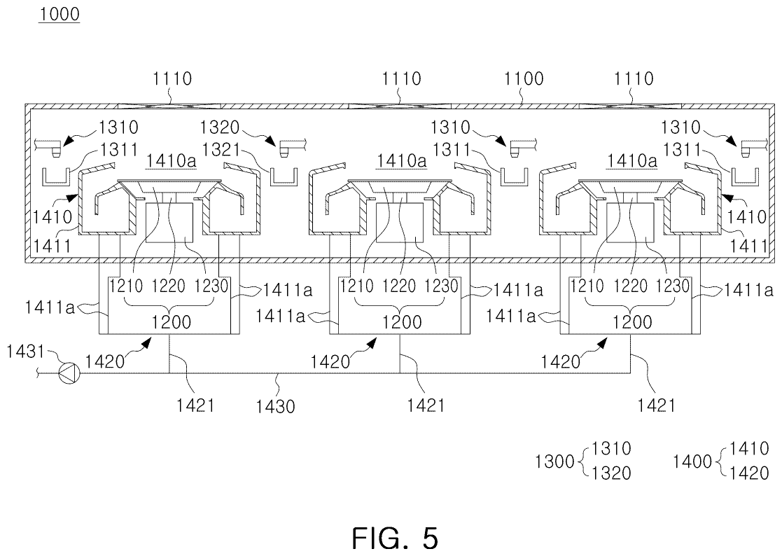

The coating chambers 410 may all have the same structure, but the types of chemicals used in each coating chamber 410 may be different from each other. The chemicals may be chemicals for forming a photoresist film or an anti-reflection film. The substrate treatment apparatus including the coating chamber 410 will be described below with reference to FIG. 5.

The baking chamber 510 has an internal treatment space equipped with a support unit 511 and a heater 512 built into the support unit 511, and the coating robot 432 heat-treats the substrate S when the substrate S is settled on the support unit 511. For example, the baking chamber 510 performs a prebake process of heating the substrate S to a predetermined temperature before coating the substrate S with the photoresist and removing organic substances or moisture from a surface of the substrate S, or a soft bake process performed after coating the substrate S with the photoresist, and performs a cooling process of cooling the substrate S after each heating process.

The interface module 600 connects the coating and development module 400 to an exposure device 700. The interface module 600 includes an interface frame 610, a first interface buffer 620, a second interface buffer 630, and a transfer robot 640, and the transfer robot 640 transfers the substrate transferred to the first and second interface buffers 620 and 630 after the coating and development module 400 is completed, to the exposure device 700. The first and second interface buffers 620 and 630 include a housing 621 and a support 622, and the transfer robot 640 and the coating robot 432 load/unload the substrate S to/from the support 622.

Hereinafter, the structure of a substrate treatment apparatus including a process chamber will be described in detail. As an example, the process chamber provided to a coating and development module will be described. In the process chamber, a treatment process of forming a film such as a protective film or an anti-reflection film on a substrate may be performed in a treatment space inside the process chamber. Additionally, in the process chamber, a treatment process of developing the substrate by supplying a developer to the substrate may be performed in the treatment space inside the process chamber.

FIG. 5 is a schematic diagram illustrating the inside of a substrate treatment apparatus according to the present disclosure.

Referring to FIG. 5, a substrate treatment apparatus 1000 may include a process chamber 1100, a support unit 1200, a nozzle unit 1300, and an exhaust unit 1400.

The process chamber 1100 is provided in a rectangular cylinder shape having an internal space. An opening (not illustrated) may be formed on one side of the process chamber 1100. The opening may function as a passage through which the substrate S is loaded and unloaded. A door (not illustrated) is installed in the opening, and the door may open or close the opening. On an upper wall of the process chamber 1100, a fan filter unit 1110 supplying a downward airflow to an internal space thereof may be disposed. The fan filter unit 1110 may include a fan introducing external air into the internal space and a filter filtering the external air. A plurality of fan filter units 1110 may be disposed in upper portions of each of the plurality of bowls 1410. A plurality of support units 1200 and a plurality of nozzle units 1300 may be provided in the internal space of the process chamber 1100.

The support unit 1200 may support and rotate the substrate S in an internal space 1410a of the bowl 1410. The support unit 1200 may include a support plate 1210, a driving shaft 1220, and a driving member 1230. The support plate 1210 may have a circular upper surface. The support plate 1210 may have a smaller diameter than that of the substrate S. The support plate 1210 is provided to support the substrate S by vacuum pressure. Optionally, the support plate 1210 may have a mechanical clamping structure supporting the substrate S. The driving shaft 1220 is coupled to a center of a lower surface of the support plate 1210, and the driving member 1230 supplying rotational force to the driving shaft 1220 may be provided on the driving shaft 1220. The driving member 1230 may be a motor. Although not illustrated in the drawing, a lifting driving member adjusting a relative height of the support plate 1210 and the bowl 1410 may be provided in the support unit 1200.

The nozzle unit 1300 may supply the chemical onto the substrate S. The nozzle unit 1300 may include a first nozzle 1310 and a second nozzle 1320. A plurality of first nozzles 1310 are provided, and the chemicals may be supplied to the substrates S provided to each of the support units 1200. The first nozzle 1310 may be provided to supply the same type of liquid. According to an embodiment, the first nozzle 1310 may supply a rinse liquid for cleaning the substrate S. For example, the rinse liquid may be water. According to another embodiment, the first nozzle 1310 may supply a removal liquid for removing photoresist from an edge region of the substrate S. For example, the removal liquid may be a thinner. The first nozzle 1310 may be rotated between a process position and a standby position around a rotation axis thereof. The process position is a position for discharging the chemical to the substrate S, and the standby position may be a position in which the chemical waits in a first standby port 1311 between the bowls 1410 when the chemical is not discharged from the first nozzle 1310. The second nozzle 1320 supplies a treatment liquid to the substrate S provided to the support unit 1200. The treatment liquid may be a photoresist. The second nozzle 1320 may be moved along the guide between a first process position, a second process position, a third process position, and the standby position. The first process position to the third process position may be positions for supplying the treatment liquid to the substrate S supported by the plurality of support units 1200. The standby position may be a position in which the chemical waits in a second standby port 1321 disposed between the bowls 1410 when the photoresist is not ejected from the second nozzle 1320.

The exhaust unit 1400 may include a bowl 1410 and an exhaust duct 1420.

Here, a plurality of bowls 1410 may be disposed in the process chamber 1100. Each of the plurality of bowls 1410 may have an internal space 1410a, and the internal space 1410a may be provided so that an upper portion thereof is open.

Additionally, the exhaust duct 1420 may be disposed in plural so as to be installed in each of the plurality of bowls 1410. The exhaust duct 1420 is connected to the bowl 1410 through a plurality of exhaust pipes 1411a of the bowl 1410. Each of the plurality of exhaust ducts 1420 may be connected to an integrated duct 1430 through a exhaust portion 1421. The integrated duct 1430 may be disposed on one side of a plurality of exhaust portions 1421 in an arrangement direction. The integrated duct 1430 may be provided with a decompression member 1431 supplying fluid pressure for exhaust. For example, the decompression member 1431 may be a pump or a fan.

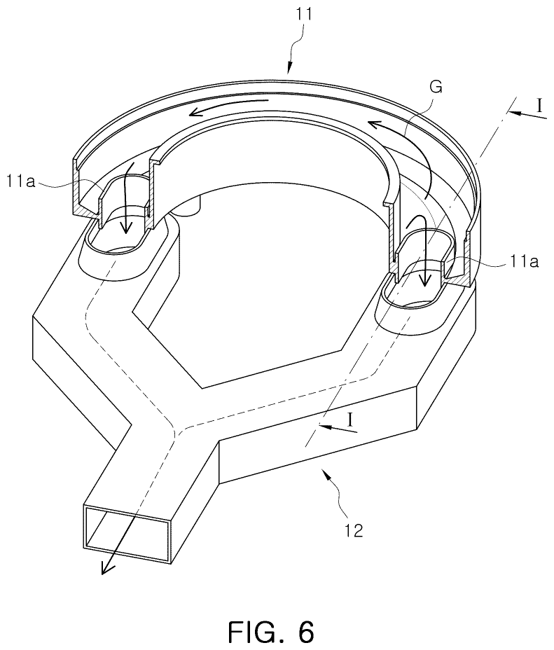

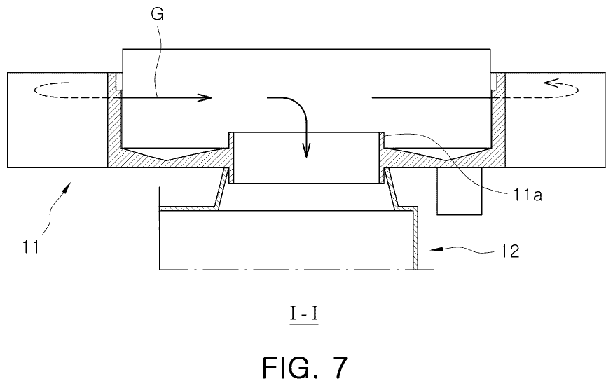

Meanwhile, before describing the bowl according to the present disclosure in detail, the bowl of the conventional art will be described with reference to FIGS. 6 and 7 as follows.

Gas G introduced into a bowl 11 is exhausted to a lower side of the bowl 11. To this end, the bowl 11 is connected to an exhaust duct 12 in a lower portion thereof, and the exhaust duct 12 is structured to communicate with the bowl 11 by an exhaust pipe 11a formed in the lower side of the bowl 11. For reference, the drawing shows a portion of the lower side of the bowl 11.

When the chemical is ejected onto the substrate through the nozzle unit, the support unit disposed inside the bowl 11 rotates the substrate. The substrate rotates due to the rotation of the support unit, and accordingly, a rotating flow in which the gas G rotates is generated in the internal space of the bowl 11.

As the rotation speed of the substrate increases, the rotation speed of the gas G also increases, but when the rotation speed of the gas G increases, the gas G may not be smoothly exhausted to the exhaust duct 12 connected to the lower portion of the bowl 11. In order for the rotating gas G to be smoothly exhausted from the bowl 11, the gas G should flow smoothly toward the exhaust duct 12 on a lower side, but the exhaust may not be smoothly performed due to the flow resistance generated by the exhaust pipe 11a vertically erected.

Specifically, as the rotation speed of the gas G increases, it is more difficult to perform the exhaust through the exhaust pipe 11a on the lower side, so that the exhaust efficiency of the gas in the bowl 11 decreases, and accordingly, the gas pressure in the bowl 11 increases, causing a backflow. Accordingly, since the substrate is contaminated by particles included in the gas backflow, there may be a problem that a defect rate of the substrate increases.

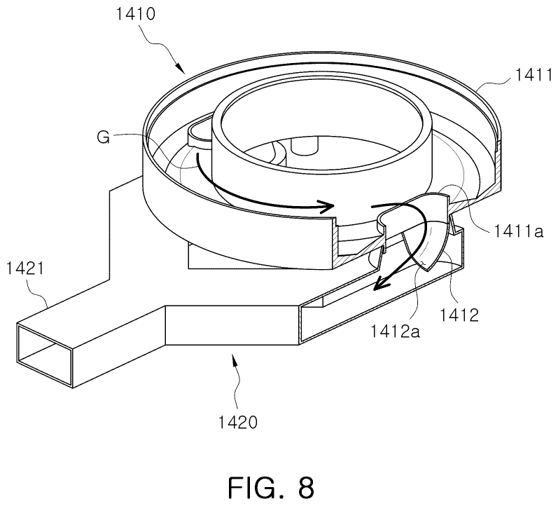

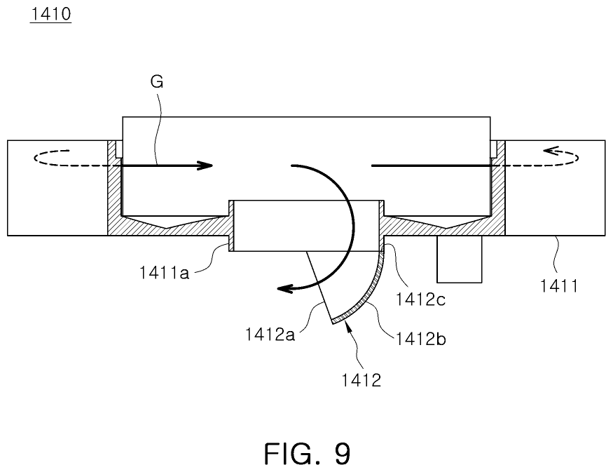

FIG. 8 is a cutaway perspective view illustrating an exhaust duct of the substrate treatment apparatus of FIG. 5 and a bowl according to a first embodiment, and FIG. 9 is a side view of the bowl of FIG. 8.

Referring to the drawings, the bowl 1410 according to the first embodiment of the present disclosure may include a bowl body 1411 and an outlet guide 1412. For reference, the drawings illustrate a portion of a lower side of the bowl 1410.

The bowl body 1411 may be disposed around the support unit 1200 (see FIG. 5) supporting and rotating the substrate. That is, the bowl body 1411 is disposed along a circumference of the support unit supporting the substrate so that the chemical and gas discharged to the substrate are recovered.

The bowl body 1411 may have an exhaust pipe 1411a formed in a lower portion thereof so as to be connected to the exhaust duct 1420 in a lower side. That is, the bowl body 1411 may have a structure in which the bowl body 1411 communicates with the exhaust duct 1420 in the lower side by the exhaust pipe 1411a. The exhaust pipe 1411a is a member formed in a cylindrical shape in a lower portion of the bowl body 1411, and connects an internal space of the bowl body 1411 and an internal space of the exhaust duct 1420. Through the exhaust pipe 1411a, the gas G in the internal space of the bowl body 1411 may be exhausted to the internal space of the exhaust duct 1420.

In this case, the exhaust pipe 1411a may be formed in a vertical direction.

The exhaust pipe 1411a may be formed in a lower portion of the bowl 1410 so as to be inserted into the exhaust duct 1420 so that as illustrated in the drawings of the present disclosure, the bowl 1410 and the exhaust duct 1420 are connected to each other.

Furthermore, although not illustrated in the drawings, the exhaust pipe may be formed in an upper portion of the exhaust duct so as to be inserted into the bowl so that the bowl and the exhaust duct are connected to each other.

However, in this specification, a case in which the exhaust pipe is formed in the bowl is described as an example.

The outlet guide 1412 may be formed in a lower portion of the exhaust pipe 1411a.

Specifically, the outlet guide 1412 is a structure formed downwardly in the lower portion of the exhaust pipe 1411a, and may be formed as an integral structure extending downwardly from a lower end of the exhaust pipe 1411a, or may be formed as a structure separately installed downwardly in the lower end of the exhaust pipe 1411a.

The outlet guide 1412 may have an outlet opening 1412a formed in an extension direction of the exhaust duct 1420 oriented toward the exhaust portion 1421 of the exhaust duct 1420. The outlet guide 1412 may have a form of a pipe extending from the exhaust pipe 1411a, and the outlet opening 1412a, which is a discharge portion through which gas G exits, may be formed in the extension direction of the exhaust duct 1420 oriented toward the exhaust portion 1421 of the exhaust duct 1420.

The outlet guide 1412 configured in this manner serve to guide the gas G introduced into the exhaust pipe 1411a to the exhaust portion 1421 of the exhaust duct 1420.

That is, when the gas G exhausted from the bowl body 1411 through the exhaust pipe 1411a to the exhaust duct 1420 is exhausted from the exhaust pipe 1411a to the exhaust duct 1420, an exhaust direction is guided to the exhaust portion 1421 of the exhaust duct 1420 by the outlet guide 1412.

When there is no outlet guide 1412 as in the conventional art, when the gas G is exhausted from the exhaust pipe 1411a to the exhaust duct 1420, the gas G collides with a bottom of the exhaust duct 1420 and has a vortex form, so that the exhaust does not occur smoothly.

In contrast, in the present disclosure, the exhaust direction of the gas G is guided to the exhaust portion 1421 of the exhaust duct 1420 by forming the outlet guide 1412 in a lower portion of the exhaust pipe 1411a, so that the gas G may be smoothly exhausted through the exhaust pipe 1411a.

Furthermore, the gas G may be easily introduced from the bowl body 1411 to the exhaust pipe 1411a, so that the exhaust efficiency of gas G from the bowl 1410 to the exhaust duct 1420 may be increased.

Specifically, a body 1412b of the outlet guide 1412 may be formed to curvedly extend, for example, from an upper end 1412c of the outlet guide 1412 toward the outlet opening 1412a.

The curved shape of the outlet guide 1412 may minimize the flow resistance of the gas G by the outlet guide 1412 when the gas G is drawn into the outlet guide 1412 from the exhaust pipe 1411a and when the gas G passes through the outlet guide 1412.

That is, when the gas G is drawn into the outlet guide 1412 from the exhaust pipe 1411a and when the gas G passes through the outlet guide 1412, since a direction of the gas G is not changed abruptly but gradually, so that the exhaust efficiency of the gas G from the bowl 1410 to the exhaust duct 1420 may be increased.

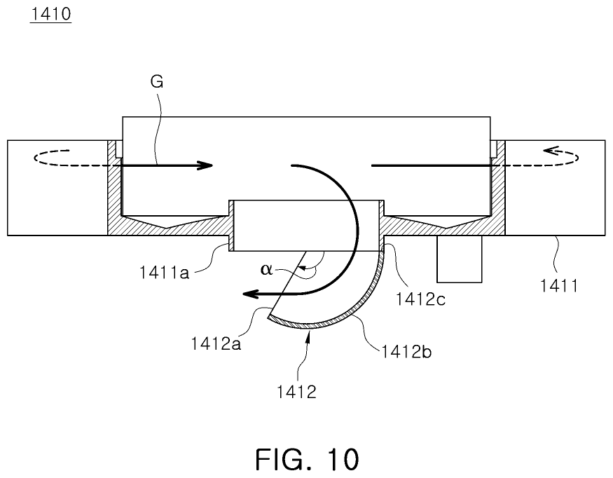

FIG. 10 is a cross-sectional view illustrating a bowl according to a second embodiment of the present disclosure.

The bowl 1410 according to the second embodiment of the present disclosure may have an angle of 10° to 130° from the upper end 1412c of the outlet guide 1412 to the outlet opening 1412a. Preferably, an angle (∝) from the upper end 1412c of the outlet guide 1412 to the outlet opening 1412a may be 45° to 120°.

For example, as illustrated in the drawing, the angle (∝) from the upper end 1412c of the outlet guide 1412 to the outlet opening 1412a may be 120°.

When the angle (∝) from the upper end 1412c of the outlet guide 1412 to the outlet opening 1412a is less than 10°, since the outlet guide 1412 guiding the gas G is significantly small, the effect of guiding the gas G to the exhaust portion 1421 of the exhaust duct 1420 (see FIG. 8) when the gas G is exhausted from the exhaust pipe 1411a to the exhaust duct 1420 is minimal. That is, since the outlet opening 1412a is closer to a bottom direction of the exhaust duct 1420 than an extension direction of the exhaust duct 1420 oriented toward the exhaust portion 1421 of the exhaust duct 1420, the gas G may have a vortex form when the gas G is exhausted from the exhaust pipe 1411a to the exhaust duct 1420, so that the effect of guiding the gas G to the exhaust portion 1421 is almost nonexistent.

Additionally, when the angle (∝) from the upper end 1412c of the outlet guide 1412 to the outlet opening 1412a is greater than 130°, the outlet guide 1412 guiding the gas G is elongated, so that the effect of guiding the gas G to the exhaust portion 1421 of the exhaust duct 1420 when the gas G is exhausted from the exhaust pipe 1411a to the exhaust duct 1420 is minimal. In other words, since the outlet opening 1412a is excessively directed toward the exhaust pipe 1411a on the upper side, the gas G may be changed into a vortex form when the gas G is exhausted from the exhaust pipe 1411a to the exhaust duct 1420. For this reason, the effect of the outlet guide 1412 guiding the gas G to the exhaust portion 1421 is almost nonexistent.

Furthermore, except for an angle structure of the outlet guide 1412 described above in the second embodiment, the basic structure of the outlet guide 1412, and the exhaust pipe 1411a formed in the bowl body 1411 together with the bowl body 1411 are the same as the first embodiment illustrated in FIG. 9, and therefore, descriptions thereof are omitted.

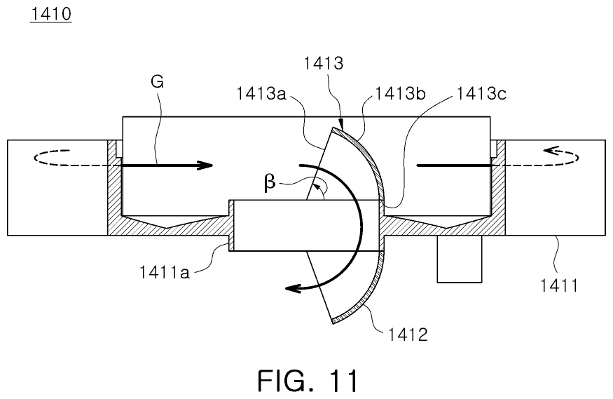

FIG. 11 is a cross-sectional view illustrating a bowl according to a third embodiment of the present disclosure.

Referring to FIG. 11, the bowl 1410 according to the third embodiment of the present disclosure may further include an inlet guide 1413 in addition to the outlet guide 1412 of FIG. 9.

The inlet guide 1413 may be formed in an upper portion of the exhaust pipe 1411a. Specifically, the inlet guide 1413 is a structure formed upwardly in the upper portion of the exhaust pipe 1411a, and may be formed as an integral structure extending upwardly from an upper end of the exhaust pipe 1411a, or may be formed as a structure separately installed upwardly in the upper end of the exhaust pipe 1411a.

The inlet guide 1413 may have an inlet opening 1413a formed to at least partially face a rotational direction of the gas G. The inlet guide 1413 may have a pipe form extending from the exhaust pipe 1411a, and may be formed so that the inlet opening 1413a, which is an inlet portion through which the gas G enters, at least partially faces the rotational direction of the gas G.

The inlet guide 1413 configured in this manner serves to guide the gas G rotating within the bowl body 1411 to the exhaust pipe 1411a.

That is, when the gas G rotating within the bowl body 1411 is exhausted from the bowl body 1411 to the exhaust pipe 1411a, the exhaust direction is guided to the exhaust pipe 1411a by the inlet guide 1413.

In this manner, since the inlet guide 1413 of the present disclosure is formed in the upper portion of the exhaust pipe 1411a to guide the exhaust direction of the gas G to the exhaust pipe 1411a, the exhaust of the gas G through the exhaust pipe 1411a may be smoothly performed.

Furthermore, since the gas G is easily introduced from the bowl body 1411 to the exhaust pipe 1411a, the exhaust efficiency of the gas G from the bowl 1410 to the exhaust duct 1420 (FIG. 8) may be increased.

Specifically, a body 1413b of the inlet guide 1413 may be formed to curvedly extend, for example, from a lower end 1413c of the inlet guide 1413 to the inlet opening 1413a.

The curved shape of the inlet guide 1413 may minimize the flow resistance of the gas G by the inlet guide 1413 when the gas G is drawn from the bowl body 1411 into the inlet guide 1413 and when the gas G passes through the inlet guide 1413.

That is, when the gas G is drawn from the bowl body 1411 into the inlet guide 1413 and when the gas G passes through the inlet guide 1413, since the direction of gas G is changed gradually rather than abruptly, so that the exhaust efficiency of gas G from the bowl 1410 to the exhaust duct 1420 may be increased.

Furthermore, the bowl 1410 of the present disclosure may have an angle (B) of 10° to 130° from the lower end 1413c of the inlet guide 1413 to the inlet opening 1413a. Preferably, the angle (B) from the lower end 1413c of the inlet guide 1413 to the inlet opening 1413a may be 45° to 120°.

When the angle (B) from the lower end 1413c of the inlet guide 1413 to the inlet opening 1413a is less than 10°, since the inlet guide 1413 guiding the gas G is significantly small, the effect of guiding the gas G from the bowl body 1411 to the exhaust pipe 1411a is minimal. That is, since the inlet opening 1413a does not almost face the rotational direction of the gas G, the gas G rotating in the bowl body 1411 barely flows into the inlet opening 1413a, so that the effect of guiding the gas G toward the exhaust pipe 1411a is almost nonexistent.

Additionally, when the angle (B) from the lower end 1413c of the inlet guide 1413 to the inlet opening 1413a is greater than 130°, since the inlet guide 1413 guiding the gas G is formed to be significantly long, the effect of guiding the gas G rotating in the bowl body 1411 to the exhaust pipe 1411a is minimal. That is, since the inlet opening 1413a is excessively directed toward the exhaust pipe 1411a on a lower side, the gas G rotating within the bowl body 1411 barely flows into the inlet opening 1413a, so that the effect of guiding the gas G toward the exhaust pipe 1411a is almost nonexistent.

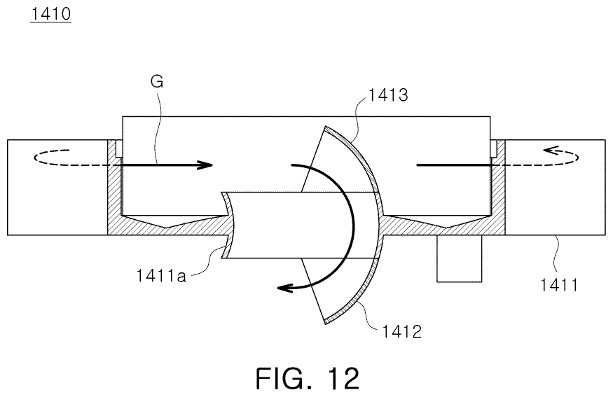

FIG. 12 is a cross-sectional view illustrating a bowl according to a fourth embodiment of the present disclosure.

Referring to FIG. 12, the exhaust pipe 1411a may have a convex curved shape in the rotational direction of the gas G inside the bowl body 1411.

The curved shape of the exhaust pipe 1411a may minimize the flow resistance of the gas G by the exhaust pipe 1411a when the gas G passes through the exhaust pipe 1411a.

That is, when the gas G passes through the exhaust pipe 1411a, the direction of the gas G is not changed abruptly but gradually, so that the exhaust efficiency of the gas G from the bowl 1410 to the exhaust duct 1420 (see FIG. 8) may be increased.

Additionally, the exhaust pipe 1411a may be formed by being connected to the outlet guide 1412 and the inlet guide 1413 as illustrated in FIG. 12.

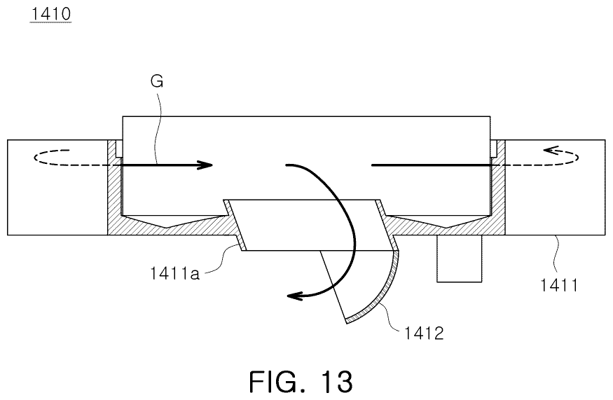

FIG. 13 is a cross-sectional view illustrating a bowl according to a fifth embodiment of the present disclosure.

Referring to FIG. 13, the exhaust pipe 1411a may be formed to be inclined toward the rotational direction of the gas G inside the bowl body 1411 as the exhaust pipe 1411a moves downwardly.

The inclined shape of the exhaust pipe 1411a may minimize the flow resistance of the gas G due to the exhaust pipe 1411a when the gas G passes through the exhaust pipe 1411a.

That is, when gas G passes through the exhaust pipe 1411a, since the direction of gas G is similar to the rotational direction of gas G in the bowl body 1411, the exhaust efficiency of gas G from the bowl 1410 to the exhaust duct 1420 (see FIG. 8) may be increased.

Furthermore, the inclined exhaust pipe 1411a may be formed by being connected to the outlet guide 1412 as illustrated in FIG. 13.

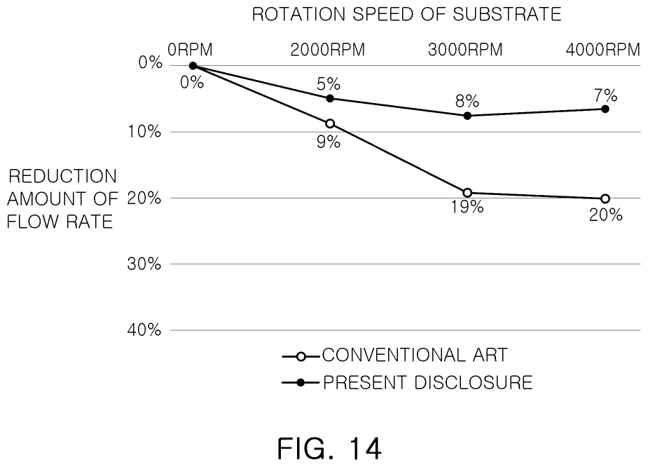

FIG. 14 is a graph illustrating a comparison between the conventional art and the present disclosure according to the third embodiment of FIG. 11, with respect to a reduction amount of flow rate of gas passing through an exhaust pipe.

Referring to FIGS. 11 and 14, when the rotation speed of the substrate increases and the gas rotation speed inside the bowl body 1411 increases, the reduction amount of flow rate of gas passing through the exhaust pipe 1411a is smaller in the present disclosure including the outlet guide 1412 and the inlet guide 1413 than in the conventional art.

That is, according to the conventional art, when the rotation speed of the substrate is 2000 RPM, 3000 RPM, and 4000 RPM, the reduction amount of flow rate of gas passing through the exhaust pipe 1411a is 9%, 19%, and 20%, respectively, but according to the present disclosure, when the rotation speed of the substrate is 2000 RPM, 3000 RPM, and 4000 RPM, the reduction amount of flow rate of gas passing through the exhaust pipe 1411a is 58, 8%, and 7%, respectively.

Accordingly, although not illustrated in the drawing, the present disclosure including the outlet guide 1412 and the inlet guide 1413 prevents the gas inside the bowl body 1411 from flowing backwards toward an upper side of the bowl body 1411 until the rotation speed of the substrate reaches 4000 RPM.

In this manner, the present disclosure includes the outlet guide 1412 and the inlet guide 1413 to increase the exhaust efficiency of the gas from the bowl 1410 toward the exhaust duct (1420 in FIG. 8), as compared to the conventional art, and thus, even if the rotation speed of the gas increases, the reduction amount of flow rate of the gas passing through the exhaust pipe may be reduced.

Furthermore, the present disclosure may prevent the occurrence of substrate defects by preventing the backflow of gas inside the bowl 1410.

Although embodiments of the present disclosure have been described with reference to the accompanying drawings, it will be understood by those skilled in the art that the present disclosure may be implemented in other specific forms without changing its technical concepts or essential features. Therefore, it should be understood that the example embodiments described above are exemplary and not limited in all respects.

What is claimed is:

1. A bowl, comprising:
a bowl body disposed around a support unit supporting and rotating a substrate, and having an exhaust pipe formed in a lower portion thereof to be connected to an exhaust duct disposed in a lower side thereof; and
an outlet guide formed in a lower portion of the exhaust pipe and having an outlet opening formed in an extension direction of the exhaust duct oriented toward an exhaust portion so as to guide gas introduced into the exhaust pipe from the bowl body, to the exhaust portion of the exhaust duct.

2. The bowl according to claim 1,
wherein a body of the outlet guide is formed by curvedly extending from an upper end of the outlet guide toward the outlet opening.

3. The bowl according to claim 2,
wherein an angle from the upper end of the outlet guide to the outlet opening is 10° to 130°.

4. The bowl according to claim 1,
wherein the exhaust pipe is formed in a vertical direction.

5. The bowl according to claim 1,
wherein the exhaust pipe has a convexly curved shape in a rotational direction of the gas within the bowl body.

6. The bowl according to claim 1,
wherein the exhaust pipe is formed to be inclined in a rotational direction of the gas within the bowl body as the exhaust pipe moves downwardly.

7. The bowl according to claim 1, further comprising:
an inlet guide formed in an upper portion of the exhaust pipe and having an inlet opening formed therein to at least partially face a rotational direction of the gas within the bowl body.

8. The bowl according to claim 7,
wherein a body of the inlet guide is formed to curvedly extend from a lower end of the inlet guide to the inlet opening.

9. The bowl according to claim 8,
wherein an angle from the lower end of the inlet guide to the inlet opening is 10° to 130°.

10. A bowl, comprising:
a bowl body disposed around a support unit supporting and rotating a substrate and having an exhaust pipe formed in a lower portion thereof to be connected to an exhaust duct disposed in a lower side thereof; and
an inlet guide formed in an upper portion of the exhaust pipe, and having an inlet opening formed therein to at least partially face a rotational direction of gas within the bowl body so as to guide the gas within the bowl body to the exhaust pipe.

11. The bowl according to claim 10,
wherein a body of the inlet guide is formed by curvedly extending from a lower end of the inlet guide to the inlet opening.

12. The bowl according to claim 10,
wherein an angle from a lower end of the inlet guide to the inlet opening is 10° to 130°.

13. The bowl according to claim 10,
wherein the exhaust pipe is formed in a vertical direction.

14. The bowl according to claim 10,
wherein the exhaust pipe has a convexly curved shape in the rotational direction of the gas within the bowl body.

15. The bowl according to claim 10,
wherein the exhaust pipe is formed to be inclined toward the direction rotation of the gas within the bowl body as the exhaust pipe moves downwardly.

16. A substrate treatment apparatus, comprising:
a process chamber;
a support unit supporting and rotating a substrate within the process chamber;
a nozzle unit discharging a chemical to the substrate;
a bowl disposed within the process chamber;
an exhaust duct disposed in a lower side of the bowl and having an exhaust portion formed therein;
an exhaust pipe formed in a lower portion of the bowl to be inserted into the exhaust duct or formed in an upper portion of the exhaust duct to be inserted into the bowl, so as to connect the bowl and the exhaust duct;
an outlet guide formed in the lower portion of the exhaust pipe and having an outlet opening formed in an extension direction of the exhaust duct oriented toward an exhaust portion of the exhaust duct; and
an inlet guide formed in an upper portion of the exhaust pipe, and having an inlet opening formed to at least partially face a rotational direction of gas within the bowl.

17. The substrate treatment apparatus according to claim 16, wherein a body of the outlet guide is formed by curvedly extending from an upper end of the outlet guide to the outlet opening, and
a body of the inlet guide is formed by curvedly extending from a lower end of the inlet guide to the inlet opening.

18. The substrate treatment apparatus according to claim 17, wherein an angle from the upper end of the outlet guide to the outlet opening is 10° to 130°, and
an angle from the lower end of the inlet guide to the inlet opening is 10° to 130°.

19. The substrate treatment apparatus according to claim 16, wherein the exhaust pipe has a convexly curved shape in the rotational direction of the gas in the bowl.

20. The substrate treatment apparatus according to claim 16, wherein the exhaust pipe is formed to be inclined toward the rotational direction of the gas inside the bowl as the exhaust pipe moves downwardly.
